(19) United States
(12) Patent Application Publication
(10) Pub. No.: US 2011/0241109 A1
(43) Pub. Date: Oct. 6, 2011

(54) Power NLDMOS array with enhanced self-protection

(75) Inventor: Vladislav Vashchenko, Palo Alto, CA (US)

(73) Assignee: National Semiconductor Corporation

(21) Appl. No.: 12/798,270

(22) Filed: Apr. 1, 2010

(51) Int. Cl. H01L 27/088; H01L 21/265

(52) U.S. Cl. 257/337; 438/514; 257/E27.06; 257/E21.334

(57) ABSTRACT

In a self protected NLDMOS array, a deep implant is included on the drain side of each NLDMOS device to balance ESD current.

### FIELD OF THE INVENTION

The present invention relates to NLDMOS arrays. In particular it relates to NLDMOS arrays with self-protection capability for use in high power applications.

### BACKGROUND OF THE INVENTION

Power products such as dc-dc convertors, controllers, LED drivers, LMUs etc., are typically implemented as arrays and are commonly designed using power optimization processes (POP) which optimizes the drain-source resistance Rdson versus drain breakdown voltage BVDSS, resulting in a very narrow or even negative electrostatic discharge (ESD) protection window. This is a particular problem in protecting the power pins in large and midsize arrays that have been developed using POPs. Thus, for example, Switch pins in buck and boost dc-dc converters, current sinks and LED drivers can experience high transient voltages during operation that are not much different to the pulsed safe operating area (SOA) limits. This low voltage margin, coupled with the fact that transient voltages at the pins are very fast, makes these devices unsuitable for ESD protection by separate explicit snapback clamps due to the inherent latch-up problems. Such arrays therefore have to rely on self-protection.

The first inclination would be to argue that larger arrays should provide greater self protection. However this is only partially true since the self protection capability is not a linear function of array size. The safe pulse current capabilities of an array are in fact a function of two current components: the monopolar channel current and the avalanche current component. Tests have shown that the monopolar channel current is a function of initial gate biasing as depicted in FIG. 1, which shows (especially for the smaller arrays as depicted by curve 100) that increased initial gate biasing (x-axis) increases the robustness (y-axis) of the array.

However, gate biasing does not address the avalanche current component. At certain ESD stress levels the arrays often operate in a non-linear fashion leading to current filamentation effects and local burnout at relatively low currents. Thus the SOA of the array is not simply scalable due to local snapback effects.

### SUMMARY OF THE INVENTION

According to the invention there is provided a self protected NLDMOS array comprising multiple NLDMOS devices, each NLDMOS device including an n+ drain and an n+ source, wherein an n-type deep implant is formed in the device. The device may include an n-buried layer (NBL) and the n-type deep implant may include an n-sinker extending downwardly between the n+ drain and the NBL or off-set laterally from the n+drain. The deep implant may be implemented using insulated gate bipolar transistor (IGBT) technology in which process steps used in making an n-type drift region for an IGBT are used to provide the deep implant of the NLDMOS device. The device may be implemented on a bulk substrate wherein the n-type deep implant is defined by an n-type epitaxial region below the active region. The device may be implemented using thin film or membrane technology. The n-type deep implant may have a doping level of 10¹⁸ cm⁻³. The n-type deep implant may be spotted or patterned. The n-type deep implant may take the form of an n-well.

Further, according to the invention, there is provided a method of controlling the ESD breakdown voltage of an NLDMOS array, that includes multiple NLDMOS devices, each NLDMOS device including an n+ drain an n+ source, and a gate between the n+ drain and the n+ source, the method comprising, forming an n-type deep implant in the device. The deep implant may be formed to extend vertically below the n+ drain or at a location on the drain side of the gate between the n+ drain and the n+ source. In order to control the breakdown voltage of the array, the location of the deep implant between the n+ drain and the n+ source may be adjusted laterally.

### BRIEF DESCRIPTION OF THE DRAWINGS

FIG. 1 shows a set of curves illustrating the effect of initial gate bias on HBM robustness,

FIG. 2 shows a set of curves illustrating the lack of effect of drain ballasting on array robustness,

FIG. 3 is a sectional view through a prior art NLDMOS device.

FIG. 4 shows a sectional view through one embodiment of an NLDMOS type device of the invention with an n-sinker extending between an n+ drain and NBL,

FIG. 5 shows curves illustrating the effect of including a sinker at different distances from the drain diffusion left opening

FIG. 6 shows a sectional view through a prior art IGBT

FIG. 7 shows a sectional view through another embodiment of an NLDMOS type device of the invention in which an n-type deep implant is patterned, and

FIG. 8 shows a sectional view through an embodiment of an NLDMOS type device of the invention implemented in thin film technology with an n-type deep implant defined by an'underlying n-epitaxial layer.

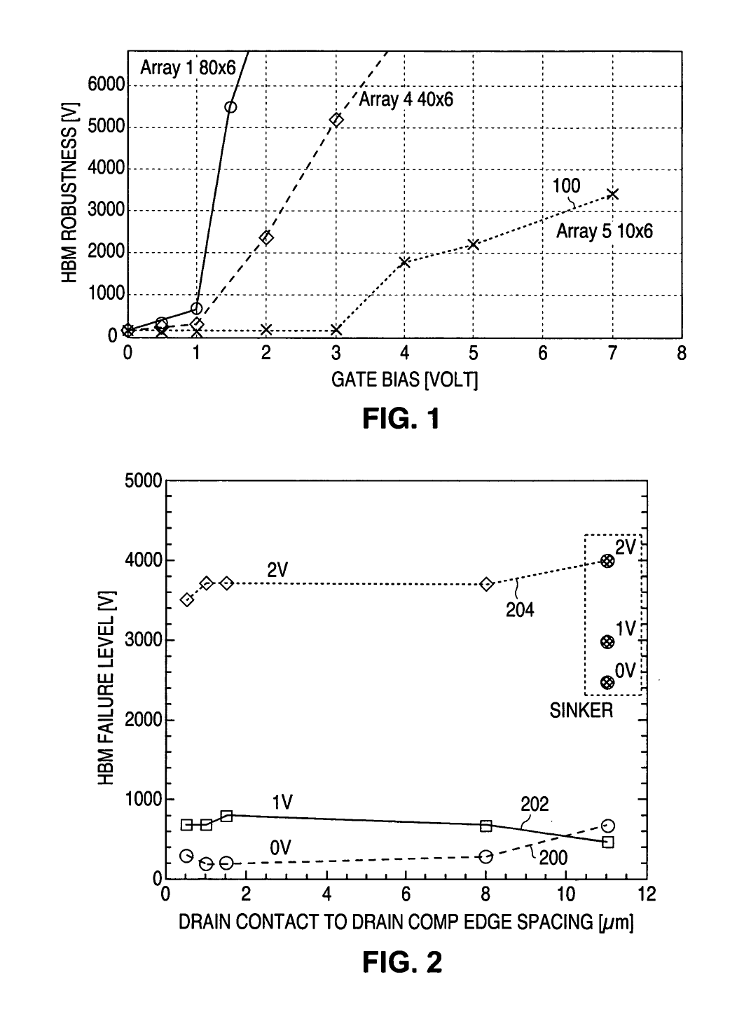

### DETAILED DESCRIPTION OF THE INVENTION

Tests with a 60 mm wide array as provided by the LM5008 resulted in local burnout at ESD pulses below 2 kV. At a 2 kV HBM (human body model) pulse the ESD current is about 1.33A, thus requiring a current density from the array before snapback of only 0.025 mA/μm. However this was not achieved by the array due to non-linear effects that cause local snapback. High voltage NLDMOS arrays typically are not capable or snapback without suffering irreversible damage. Thus, in the case of NLDMOS arrays a solution had to be found to avoid local snapback.

Typically the array is large enough to withstand ESD pulses provided the ESD current is balanced across the array. Unfortunately non-linearity characteristics of the array results in unbalanced current distribution and local snapback effects.

Since in the NLDMOS array the source and p-body are typically connected it is not possible to limit the critical current by reducing the parasitic npn base resistance. One approach that has been adopted in the past in the case of arrays of snapback NMOS devices is to balance the current by making use of unsilicided drain ballast regions. In the case of NPN arrays, poly emitter ballasting regions have been used as an approach in balancing current.

However, the present invention deals with arrays of NLDMOS devices. Tests that were conducted in solving this dilemma showed that simply increasing the length of surface structures such as the drain ballast region fails to address the problem. As shown in FIG. 2, increasing drain ballast regions (the unsilicided drain regions extending from the drain contact toward the source) had no effect on increasing the robustness of the array. Even though the length of the drain ballast region (x-axis in FIG. 2) was increased it had little effect on the robustness. The only improvement that is discernible in FIG. 2 is the result of increased gate bias as indicated by the curves 200, 202, 204.

However, as indicated above, gate bias does not address the avalanche current component. Thus a different solution had to be found for NLDMOS arrays to address avalanche current breakdown.

The present invention adopts a novel current balancing structure on the drain side of the devices. In particular, the present invention makes use of additional in depth sub-collector implants. This is best understood by considering a prior NLDMOS device.

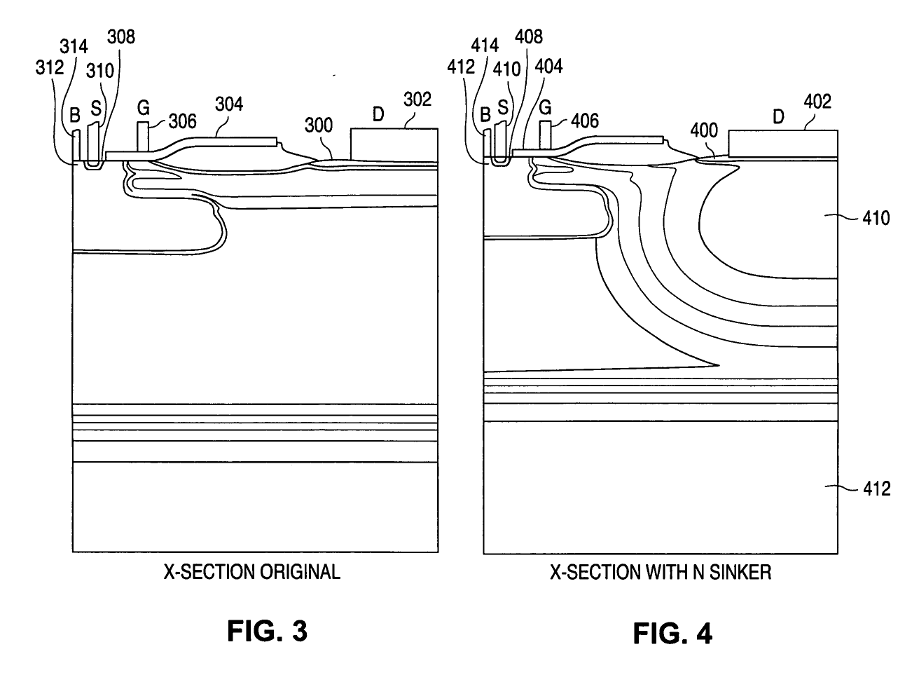

FIG. 3 shows a cross section through a prior art NLDMOS device, which includes an n+ drain 300 with drain contact 302, a gate 304 with gate contact 306, and a source 308 with source contact 310. In addition, the NLDMOS device includes a base 312 with base contact 314.

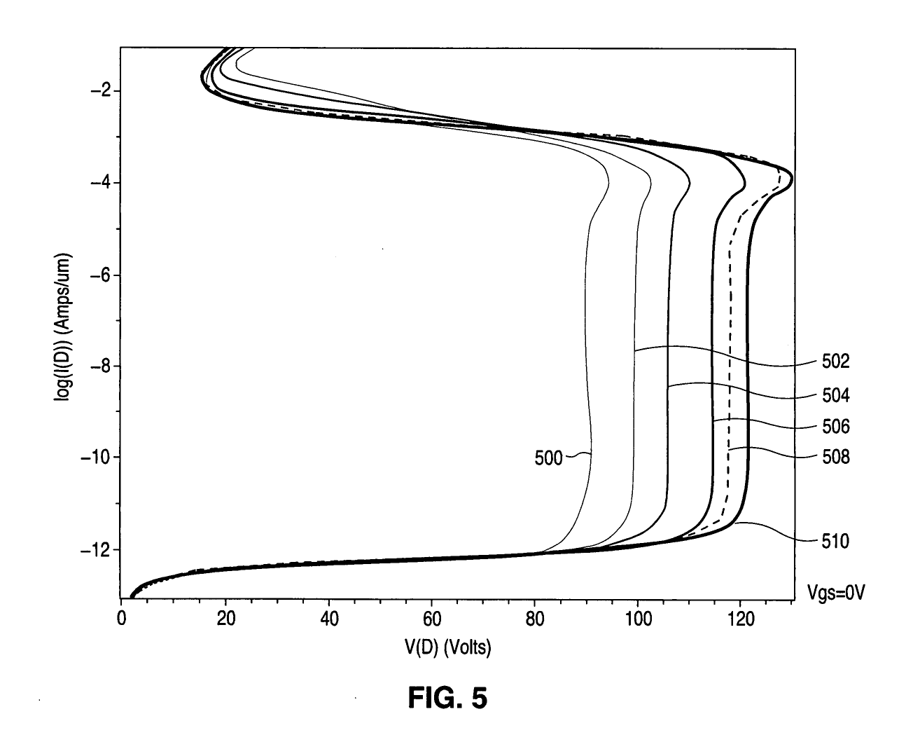

One embodiment of the present invention is shown in FIG. 4 and provides for an n-type deep implant in the form of an n-sinker 410, which in this embodiment extends vertically between the drain region 400 and an n-buried layer (NBL) 412. Other than the n-type deep implant, the NLDMOS-like structure of the present invention is substantially the same as the prior art, and includes a drain 400 with drain contact 402, a gate 404 with gate contact 406 and a source 408 with source contact 410. The present NLDMOS-like structure also includes a base 422 with base contact 424. While the embodiment of FIG. 4 had the n-sinker 410 extending between drain and NBL, in another embodiment, the sinker was formed spaced laterally from the drain. The effect of including a sinker is shown in FIG. 5 for different sinker mask locations and with no gate-source voltage.

Graph 500 shows the curve for no sinker compared to graphs 502, 504, 506, 508, 510, which shows the mask at locations 9.5, 10, 11, 12, 15 μm, respectively, measured from the left opening of the drain diffusion toward the source. Thus the closer the N-sinker mask is to the source (moved to the left), the lower the breakdown voltage The curve 500 with highest Vbr has no Nsinker.

In yet another embodiment of the invention instead of using process steps for forming a sinker (as is used for instance in forming vertical BJTs) process steps for forming an n-type epitaxial drift region in an isolated gate bipolar transistor (IGBT) cell configuration were used instead thereby defining an NLDMOS with n-type deep implant.

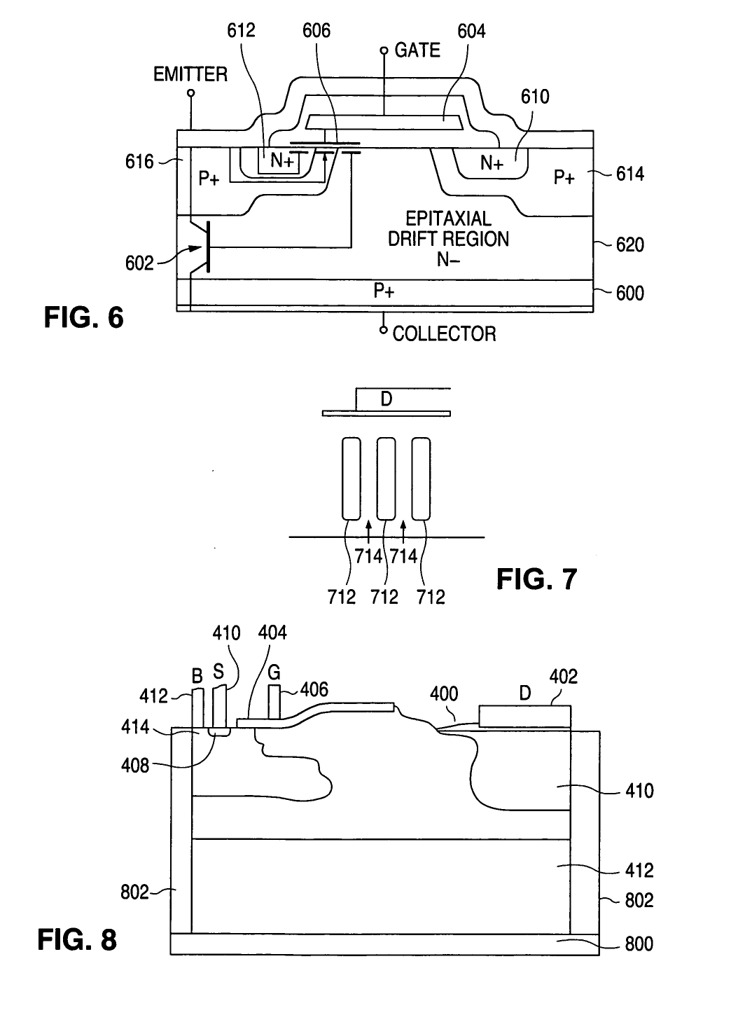

This is best understood with reference to a prior art IGBT is shown in FIG. 6. The IGBT has a configuration similarly to an n-channel vertical power MOSFET except that the n+ drain is replaced with a p+ collector layer 600, thus forming a vertical PNP bipolar junction transistor as depicted by the schematic representation of a PNP 602. It will be appreciated that the process steps of forming the isolated gate 604 of the IGBT can also be adopted to define the gate of the NLDMOS device as depicted by the schematic representation 606 of a MOSFET. The n+ drain and source regions 610, 612 of the NLDMOS are formed in p+ regions 614, 616, which are in turn formed in an n-type epitaxial drift region 620.

Thus, in one embodiment of the invention the n-type deep implant in an NLDMOS-like structure of the invention is implemented by forming the n-type epitaxial drift region 620 using IGBT manufacturing processes IGBT.

Yet another embodiment of the invention is shown in FIG. 7, which is similar to the embodiment of FIG. 4. However, in this embodiment, the sinker 710 is spaced from the drain 700 and is patterned. To define alternating regions of highly and lowly doped n-material as shown by regions 712, 714. Other patterns of high and low n-type doping can also be implemented in defining the n-type deep implant, e.g., a spotted implant. Also, it will be appreciated that several sinkers can be implemented. Such an embodiment will be similar to that shown in FIG. 4, except that the lowly doped regions 714 are defined by the doping level of the material in which the sinkers are formed.

Yet another embodiment of the invention includes an NLDMOS-type structure implemented in thin film technology as shown in FIG. 8. Structurally it is similar to the embodiment of FIG. 4 and for ease of reference the same reference numerals have been retained for equivalent structures. In addition it includes an oxide isolation layer 800 (e.g., 2 um thick) providing isolation from the substrate at a depth of 12 um in this embodiment. Deep lateral trenches 802 extend downward to the oxide layer 800. with a n-type deep implant defined by an n-type bulk substrate or an n-epitaxial region that defines the substrate of the thin film device.

In the embodiment of FIG. 4 the n-type deep implant was defined as a sinker, and in the embodiment making use of IGBT process steps, the deep implant was implemented as an n-type epitaxial drift region. The invention can also be implemented using an n-type well to define the n-type deep implant.

Thus, while the invention has been defined in terms of specific embodiments, the invention is not so limited, and can be implemented in different ways without departing from the scope of the invention.

What is claimed is:

1. A self protected NLDMOS array, comprising
multiple NLDMOS devices,
each NLDMOS device including an n+ drain and an n+ source, wherein an n-type deep implant is formed in the device.

2. An array of claim 1, wherein each device includes an n-buried layer (NBL) and the n-type deep implant includes an n-sinker extending downwardly to the NBL.

3. An array of claim 2, wherein the n-sinker extends between the n+ drain and the NBL.

4. An array of claim 3, wherein the n-sinker is off-set laterally from the n+ drain toward that n+ source.

5. An array of claim 1, wherein the deep implant in the NLDMOS device is implemented using insulated gate bipolar transistor (IGBT) technology in which process steps used in making an n-type drift region for an IGBT are used to provide the deep implant of the NLDMOS device.

6. An array of claim 1, wherein each device is implemented on a bulk substrate, the n-type deep implant being defined by n-type epitaxial region below an active region.

7. An array of claim 7, wherein the devices are implemented using thin film or membrane technology.

8. An array of claim 1, wherein the n-type deep implants have a doping level of the order of 10¹⁸ cm⁻³.

9. An array of claim 1, wherein the n-type deep implants are spotted or patterned.

10. An array of claim 1, wherein n-type deep implants comprise n-wells or portions of an n-well.

11. A method of controlling the ESD breakdown voltage of an NLDMOS array, that includes multiple NLDMOS devices, each NLDMOS device including an n+ drain an n+ source, and a gate between the n+ drain and the n+ source, the method comprising,
forming an n-type deep implant in the device.

12. A method of claim 11, wherein the deep implant is formed to extend vertically below the n+ drain or at a location on the drain side of the gate between the n+ drain and the n+ source.

13. A method of claim 12, wherein the location of the deep implant between the n+ drain and the n+ source is adjusted laterally to control the breakdown voltage.
